(19) United States
(12) Patent Application Publication
(10) Pub. No.: US 2017/0164112 A1
(43) Pub. Date: Jun. 8, 2017

(54) EARPHONE

(71) Applicant: Hang Tat MA, Hongkong (HK)

(72) Inventor: Hang Tat MA, Hongkong (HK)

(21) Appl. No.: 15/325,727

(22) PCT Filed: Jun. 26, 2015
(86) PCT No.: PCT/CN2015/082478

§ 371 Date: Jan. 12, 2017

(30) Foreign Application Priority Data
Jul. 25, 2014 (CN) 201420416722.0

(51) Int. Cl. H04R 5/04; H04R 5/033; H04R 1/40; H04R 3/12; H04R 1/10; H04R 1/34

(52) U.S. Cl. CPC H04R 5/04; H04R 1/10; H04R 1/34; H04R 1/40; H04R 3/12; H04R 5/033; H03L 7/18

(57) ABSTRACT

Disclosed is an earphone, comprising a left receiver, a right receiver and a sound source input end. A main left loudspeaker and a secondary left loudspeaker are arranged in the left receiver, and a main right loudspeaker and a secondary right loudspeaker are arranged in the right receiver. The sound source input end includes a left channel audio input end and a right channel audio input end. The left channel audio input end is electrically connected to the secondary right loudspeaker via a third frequency divider, and the right channel audio input end is electrically connected to the secondary left loudspeaker via a fourth frequency divider. The third frequency divider is configured for performing frequency division processing on audio signals input by the left channel audio input end and transmitting the same to the secondary right loudspeaker, and the fourth frequency divider is configured for performing frequency division processing on the audio signals input by the right channel audio input end and transmitting the same to the secondary left loudspeaker. With the proposed earphone, users may be able to have unprecedented, real and natural environmental listening performance.

### BACKGROUND

1. Technical Field

The present disclosure generally relates to an earphone.

2. Description of Related Art

With respect to general stereo headset products, as the sound principle and acoustic performance experienced by uses in real scenario are different, “tread effect” or “super-stereo effect” may arise regardless of simple or complicated music. This may lead to non-natural user experience, such as the music is abnormal or the music content concentrates on the user's head. Such user experience can be explained by the sound principle.

Traditional stereo headset products include separate left and right channels, and each of the channels are arranged at two lateral sides of the ears, that is, the channel are arranged at the outer sides of the ears, which is about 90 degrees away from a central portion the head. When the user wears the earphone, within the general stereo audio file, the left channel signals and the right channel signals are completely independent from each other.

That is, only the left ear can hear the sound from the left earphone, and the right ear cannot hear any sound, and the vice versa. This may result in abnormal sound field or acoustic performance with strange positioning. For instance, the sound that should have been heard in front of the user, however, it appears on the top of the head or two lateral sides of the left and the right earphones. Such strange acoustic distribution can only be experienced when using the earphone, that is, such distribution does not happen in real scenarios. Also, such performance may cause user dizzy or uncomfortable, and which may cause the user stops using earphones.

With respect to users with normal hearing capability, the left ear and the right ear can hear the sound at the same time regardless of the locations generating the sound. This is the normal user hearing habits and how user determine the direction and the position of the sound.

For instance, when the sound is from the left side, the right r receives the sound at the same time. The difference is that when the sound is transmitted from the left side to the right side, the sound may be delayed or decayed due to different distances, the head, the organs on the face, hair, and the lower body, which is referred to as head transmission effect.

As the general earphones cannot meet the above requirements, it can be understood that the substantial difference exists between the earphone and the speakers in real scenarios, which results in non-natural and non-real acoustic performance

### SUMMARY

The present disclosure relates to an earphone for providing more natural and more real acoustic performance after the sound has been converted. As such, the left and right ears of the user may experience more real acoustic performance.

In one aspect, an earphone includes: a left receiver, a right receiver, a sound source input end, a first frequency divider, and a second frequency divider, the right receiver is configured with a main right loudspeaker, the sound source input end includes a left channel audio input end and a right channel audio input end, the left channel audio input end electrically connects to the main left loudspeaker via the first frequency divider, the right channel audio input end electrically connects to the main right loudspeaker via the second frequency divider, wherein the earphone further includes a secondary left loudspeaker, a secondary right loudspeaker, a third frequency divider, and a fourth frequency divider, the secondary left loudspeaker is configured within the left receiver, the secondary right loudspeaker is configured within the right receiver, the third frequency divider electrically connects to the secondary right loudspeaker, and the third frequency divider is configured for performing a frequency division process toward audio signals inputted from the left channel audio input end and for transmitting the processed audio signals to the secondary right loudspeaker, the fourth frequency divider electrically connects to the secondary left loudspeaker, and the fourth frequency divider is configured for performing the frequency division process toward the audio signals inputted from the right channel audio input end and for transmitting the processed audio signals to the secondary left loudspeaker.

Wherein the earphone includes a left switch and a right switch, the left switch electrically connects between the left channel audio input end and the third frequency divider for turning on or off the secondary right loudspeaker, and the right switch electrically connects between the right channel audio input end and the fourth frequency divider for turning on or off the secondary left loudspeaker.

Wherein the earphone includes a bi-channel switch, the bi-channel switch electrically connects to the left switch and the right switch for turning on or off the left switch and the right switch.

Wherein the left receiver is configured with a first conduit and a second conduit, the first conduit is arranged between the main left loudspeaker and an outer surface of the left receiver, and the first conduit is configured for transmitting the audio signals from the main left loudspeaker to an outside of the left receiver, the second conduit is arranged between the secondary left loudspeaker and the outer surface of the left receiver, the second conduit is configured for transmitting the audio signals from the secondary left loudspeaker to the outside of the left receiver, a length of the second conduit is N times of the length of the first conduit, and N is an integer greater than or equal to one.

Wherein the right receiver configured with a third conduit and a fourth conduit, the third conduit is arranged between the main right loudspeaker and an outer surface of the right receiver, the third conduit is configured for transmitting the audio signals from the main right loudspeaker to an outside of the right receiver, the fourth conduit is arranged between the secondary right loudspeaker and the outer surface of the right receiver, the fourth conduit is configured for transmitting the audio signals from the secondary right loudspeaker to the outside of the right receiver, and a length of the fourth conduit is N times of the length of the third conduit, and N is an integer greater than or equal to one.

Wherein the earphone further includes a left audio line and a right audit line, the first frequency divider and the third frequency divider are configured within the left audio line, and the second frequency divider and the fourth frequency divider are configured within the right audit line.

In view of the above, the secondary left loudspeaker is configured within the left receiver, and the secondary right loudspeaker is configured within the right receiver. The secondary right loudspeaker and the secondary left, loudspeaker are configured to convert the audio signals processed by the third frequency divider and the fourth frequency divider. When the user puts on the left receiver and the right to listen to the audio files, except for the sound from by the main left loudspeaker and the main right loudspeaker, the user can also hear the sound processed by the frequency dividers. As such, the right receiver and the left receiver within the left receiver have been simulated to the hearing characteristics in real scenario, and thus the user may have unprecedented, real and natural environmental listening experience. When the earphone is in its operations, the sound will be in front of the user, instead of on top of the head. Also, the sound in the left and right ranges may be natural within a certain range, instead of being too spacious or exaggerated.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, all the views are schematic, and like reference numerals designate corresponding parts throughout the several views.

FIG. 1 is a schematic view of the earphone in accordance with one embodiment.

FIG. 2 is a schematic view showing the connected circuit modules within the earphone in FIG. 1.

FIG. 3 is a schematic view of the internal structure of the left receiver in FIG. 1.

FIG. 4 is a schematic view of the internal structure of the right receiver in FIG. 1.

### DETAILED DESCRIPTION

The disclosure is illustrated by way of example and not by way, of limitation in the figures of the accompanying drawings.

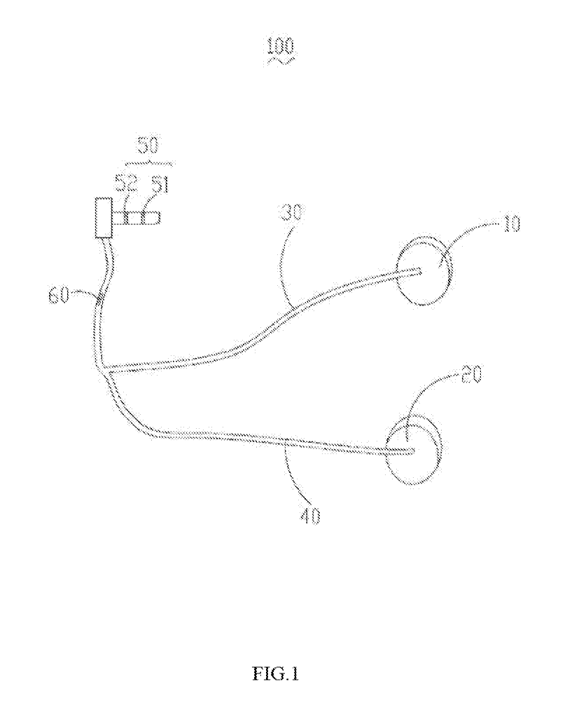

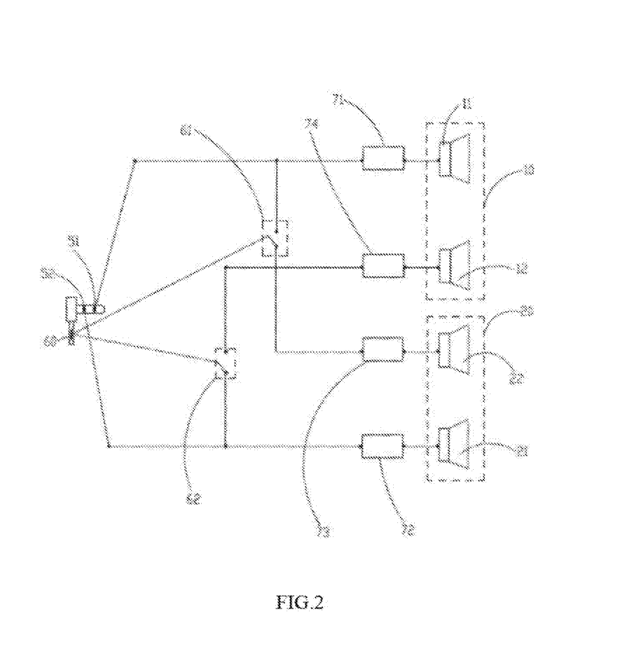

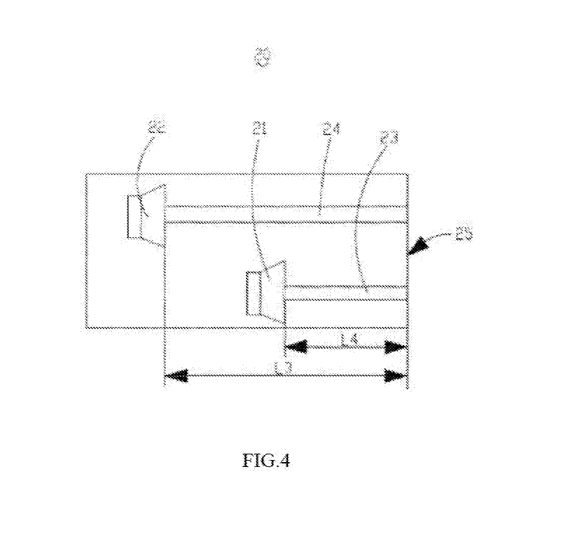

Referring to FIGS. 1-4, the earphone 100 includes a left receiver 10, a right receiver 20, a sound source input end 50, a first frequency divider 71, a second frequency divider 72, a third frequency divider 73 and a fourth frequency divider 74.

In the embodiment, the earphone 100 is an in-ear earphone. In other embodiments, the earphone 100 may be a headphone.

The left receiver 10 is configured with a main left loudspeaker 11 and a secondary left loudspeaker 12, and the right receiver 20 is configured with a main right loudspeaker 21 and a secondary right loudspeaker 22.

The sound source input end 50 includes a left channel audio input end 51 and a right channel audio input end 52. The left channel audio input end 51 electrically connects to the main left loudspeaker 11 via the first frequency divider 71, and the right channel audio input end 52 electrically connects to the main right loudspeaker 21 via the second frequency divider 72. The third frequency divider 73 electrically connects to the secondary right loudspeaker 22, and the third frequency divider 73 is configured for performing a frequency division process toward audio signals inputted from the left channel audio input end 51 and for transmitting the audio signals to the secondary right loudspeaker 22. The fourth frequency divider 74 electrically connects to the secondary left loudspeaker 12, and the fourth frequency divider 74 is configured for performing the frequency division process toward the audio signals inputted from the right channel audio input end 52 and for transmitting the audio signals to the secondary left loudspeaker 12.

In the embodiment, the earphone 100 further includes a left audio line 30 and a right audit line 40. The first frequency divider 71 and the third frequency divider 73 are configured within the left audio line 30, and the second frequency divider 72 and the fourth frequency divider 74 are configured within the fight audit line 40.

In other embodiments, the first frequency divider 71 and the third frequency divider 73 may be configured within a chamber of the left receiver 10, and the second frequency divider 72 and the fourth frequency divider 74 may be configured within a chamber of the right receiver 20.

In view of the above, the secondary left loudspeaker 12 is configured within the left receiver 10, and the secondary right loudspeaker 22 is configured within the right receiver 20. The secondary right loudspeaker 22 and the secondary left loudspeaker 12 are configured to convert the audio signals processed by the third frequency divider 73 and the fourth frequency divider 74. When the user puts on the left receiver 10 and the right receiver 20 to listen to the audio files, except for the sound emitted by the main left loudspeaker 11 and the main right loudspeaker 21, the user can also hear the sound processed by the third frequency divider 73 and the fourth frequency divider 74 configured within the left receiver 10 and the right receiver 20, and wherein the frequency of the sound processed by the third frequency divider 73 and the fourth frequency divider 74 are different from that of the sound emitted by the main left loudspeaker 11 and the main right loudspeaker 21. That is, the audio signals inputted from the right channel audio input end 52 can be heard within the left receiver 10, and the audio signals inputted from the left channel audio input end 51 can be heard within the right receiver 20. As such, the right receiver 20 and the left receiver 10 within the left receiver 10 have been simulated to the hearing characteristics in real scenario, and thus the user may have unprecedented, real and natural environmental listening experience. When the earphone 100 is in its operations, the sound will be in front of the user, instead of on top of the head. Also, the sound in the left and right ranges may be natural within a certain range, instead of being too spacious or exaggerated.

Further, the earphone 100 also includes a left switch 61, a right switch 62, and a bi-channel switch 60. The left switch 61 electrically connects between the left channel audio input end 51 and the third frequency divider 73 for turning on or off the secondary right loudspeaker 22. The right switch 62 electrically connects between the right channel audio input end 52 and the fourth frequency divider 74 for turning on or off the secondary left loudspeaker 12. The bi-channel switch 60 electrically connects between the left switch 61 and the right switch 62 for turning on or off the left. switch 61 and the right switch 62. In the embodiment, the bi-channel switch 60 is configured on the wirings of the earphone 100 so as to facilitate users' operations.

The configuration of the left switch 61, the right switch 62, and the bi-channel switch 60 enables the audio switch function of the earphone 100. The user may turn off the bi-channel switch 60, including the secondary right loudspeaker 22 and the secondary left loudspeaker 12 of the earphone 100, to obtain the traditional earphone effect. Thus, the earphone 100 may not only perform traditional operations but also the real and natural listening effect in real scenarios.

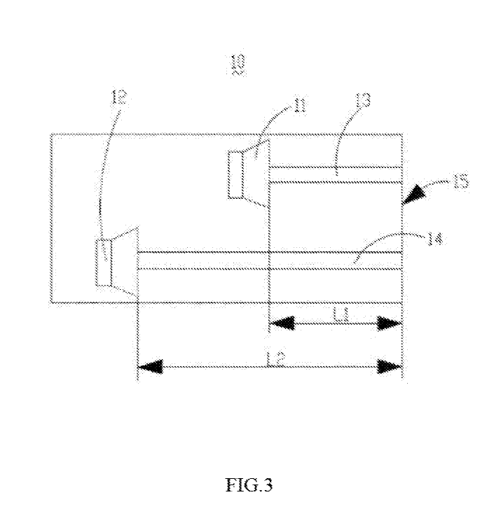

Referring to FIGS. 3 and it, specifically, the left. receiver 10 is configured with a first conduit 13 and a second conduit 14. The first conduit 13 is arranged between the main left loudspeaker 11 and an outer surface 15 of the left receiver 10. The first conduit 13 is configured for transmitting the audio signals from the main left loudspeaker 11 to an outside of the left receiver 10 such that the audio signals may be transmitted to ears of the user. The second conduit 14 is arranged between the secondary left loudspeaker 12 and the outer surface 15 of the left receiver 10. The second conduit 14 is configured for transmitting the audio signals from the secondary left loudspeaker 12 to the outside of the left receiver 10 such that the audio signals may be transmitted to ears of the user. The length L2 of the second conduit 14 is N times of the length L1 of the first conduit 13, and N is an integer greater than or equal to one. In other words, the main left loudspeaker 11 and the secondary left loudspeaker 12 are configured to be interleaved with one other in the chamber of the left receiver 10 so as to obtain the real listening effect.

Similarly, the right receiver 20 is configured with a third conduit 23 and a fourth conduit 24. The third conduit 23 is arranged between the main right loudspeaker 21 and an outer surface 25 of the right receiver 20. The third conduit 23 is configured for transmitting the audio signals from the main right loudspeaker 21 to an outside of the right receiver 20 such that the audio signals may be transmitted to ears of the user. The fourth conduit 24 is arranged between the secondary right loudspeaker 22 and the outer surface 25 of the right receiver 20. The fourth conduit 24 is configured for transmitting the audio signals from the secondary right loudspeaker 22 to the outside of the right receiver 20 such that the audio signals may be transmitted to ears of the user. The length L4 of the fourth conduit 24 is N times of the length L3 of the third conduit 23, and N is an integer greater than or equal to one. In other words, the main right loudspeaker 21 and the second=right loudspeaker 22 are configured to be interleaved with one other in the chamber of the right receiver 20 so as to obtain the real listening effect.

Although the features and elements of the present disclosure are described as embodiments in particular combinations, each feature or element can be used alone or in other various combinations within the principles of the present disclosure to the full extent indicated by the broad general meaning of the terms in which the appended claims are expressed.

What is claimed is:

1. An earphone, comprising,
a left receiver, a right receiver, a sound source input end, a first frequency divider, and a second frequency divider, the right, receiver is configured with a main right loudspeaker, the sound source input end comprises a left channel audio input end and a right channel audio input end, the left channel audio input end electrically connects to the main left loudspeaker via the first frequency divider, the right channel audio input end electrically connects to the main right loudspeaker the second frequency divider, wherein the earphone further comprises a secondary left loudspeaker, a secondary right loudspeaker, a third frequency divider, and a fourth frequency divider, the secondary left loudspeaker is configured within the left receiver, the secondary right loudspeaker is configured within the right receiver, the third frequency divider electrically connects to the secondary right loudspeaker, and the third frequency divider is configured for performing a frequency division process toward audio signals inputted from the left channel audio input end and for transmitting the processed audio signals to the secondary right loudspeaker, the fourth frequency divider electrically connects to the secondary left loudspeaker, and the fourth frequency divider is configured for performing the frequency division process toward the audio signals inputted from the right channel audio input end and for transmitting the processed audio signals to the secondary left loudspeaker.

2. The earphone as claimed in claim 1, wherein the earphone comprises a left switch and a right switch, the left switch electrically connects between the left channel audio input end and the third frequency divider for turning on or off the secondary right loudspeaker, and the right switch electrically connects between the right channel audio input end and the fourth frequency divider for turning on or off the secondary left loudspeaker.

3. The earphone as claimed in claim 2, wherein the earphone comprises a bi-channel switch, the bi-channel switch electrically connects to the left switch and the right switch for turning on or off the left switch and the right switch.

4. The earphone as claimed in claim 1, wherein the left receiver is configured with a first conduit and a second conduit, the first conduit is arranged between the main left loudspeaker and an outer surface of the left receiver, and the first conduit is configured for transmitting the audio signals from the main left loudspeaker to an outside of the left receiver, the second conduit is arranged between the secondary left loudspeaker and the outer surface of the left receiver, the second conduit is configured for transmitting the audio signals from the secondary left loudspeaker to the outside of the left receiver, a length of the second conduit is N times of the length of the first conduit, and N is an integer greater than or equal to one.

5. The earphone as claimed in claim 1, wherein the right receiver configured with a third conduit and a fourth conduit, the third conduit is arranged between the main right loudspeaker and an outer surface of the right receiver, the third conduit is configured for transmitting the audio signals from the main right loudspeaker to an outside of the right receiver, the fourth conduit is arranged between the secondary right loudspeaker and the miter surface of the right receiver, the fourth conduit is configured for transmitting the audio signals from the secondary right loudspeaker to the outside of the right receiver, and a length of the fourth conduit is N times of the length of the third conduit, and N is an integer greater than or equal to one.

6. The earphone as claimed in claim 1, wherein the earphone further comprises a left audio line and a right audit line, the first frequency divider arid the third frequency divider are configured within the left audio line, and the second frequency divider and the fourth frequency divider are configured within the right audit line.
